(19) United States
(12) Patent Application Publication
(10) Pub. No.: US 2019/0055652 A1
(43) Pub. Date: Feb. 21, 2019

(54) INJECTOR OF SILICON FOR THE SEMICONDUCTOR INDUSTRY

(71) Applicant: SICO TECHNOLOGY GMBH, Bleiberg-Kreuth (AT)

(72) Inventors: Walter NADRAG, Bad Bleiberg (AT); Enrico NADRAG, Bad Bleiberg (AT)

(21) Appl. No.: 16/065,227

(22) PCT Filed: Dec. 19, 2016
(86) PCT No.: PCT/EP2016/081788

§ 371 Date: Jun. 22, 2018

(30) Foreign Application Priority Data
Dec. 22, 2015 (AT) A 815/2015

(51) Int. Cl. C23C 16/455; C23C 16/458; C23C 16/448; H01L 21/67

(52) U.S. Cl. CPC C23C 16/45578; H01L 21/67017; C23C 16/4485; C23C 16/4583

(57) ABSTRACT

An injector (1), which is produced from silicon and allows gas to be introduced into process chambers in processes, in particular processes in semiconductor technology, is proposed. The injector (1) is formed as a tube (2), which if appropriate consists of at least two pieces of tube (10) and in which outlet openings for the gas to be introduced into the process chamber are provided. At least one channel (4) is provided in the tube (2) that serves as an injector (1). The profile of the tube (2) serving as the injector (1) is unround, and therefore deviates from a circular profile, with elongated, triangular or star-shaped forms being possible options.

The invention relates to an injector with the features of the introductory part of claim 1. During wafer production, wafers are inserted into holding devices (boats) and brought into treatment spaces (ovens), in which they are treated with gas.

The gas, with which wafers are treated, is introduced into the oven via an injector, which normally is a bent or angled tube made of quartz glass that is provided with holes.

US 2006/0185589 A1 describes an injector made of silicon for gas, which can be used during thermal treatment of semiconductor wafers. The drawings, for example FIG. 2 of US 2006/0185589 A1, show that the injector has a bore that is circular in cross-section and is formed from half-shells. The outside shape of the tube is, for example, rectangular. FIG. 11 of US 2006/0185589 A1 shows that the free end of the tube is closed and that outlet openings are provided in the tube. In the case of US 2006/0185589 A1, the injector is put together from half-shells, which is problematic in the case of the conditions under which generic injectors are used.

U.S. Pat. No. 5,943,471 A deals in particular with the evaporation of solids for a CVD method. The device that is described in U.S. Pat. No. 5,943,471 A comprises a hollow component that is connected to an injector, which communicates with an input opening and a reaction chamber, which contains the substrate. In U.S. Pat. No. 5,943,471 A, there is no information on the material of which the components of the device for the CVD method can consist.

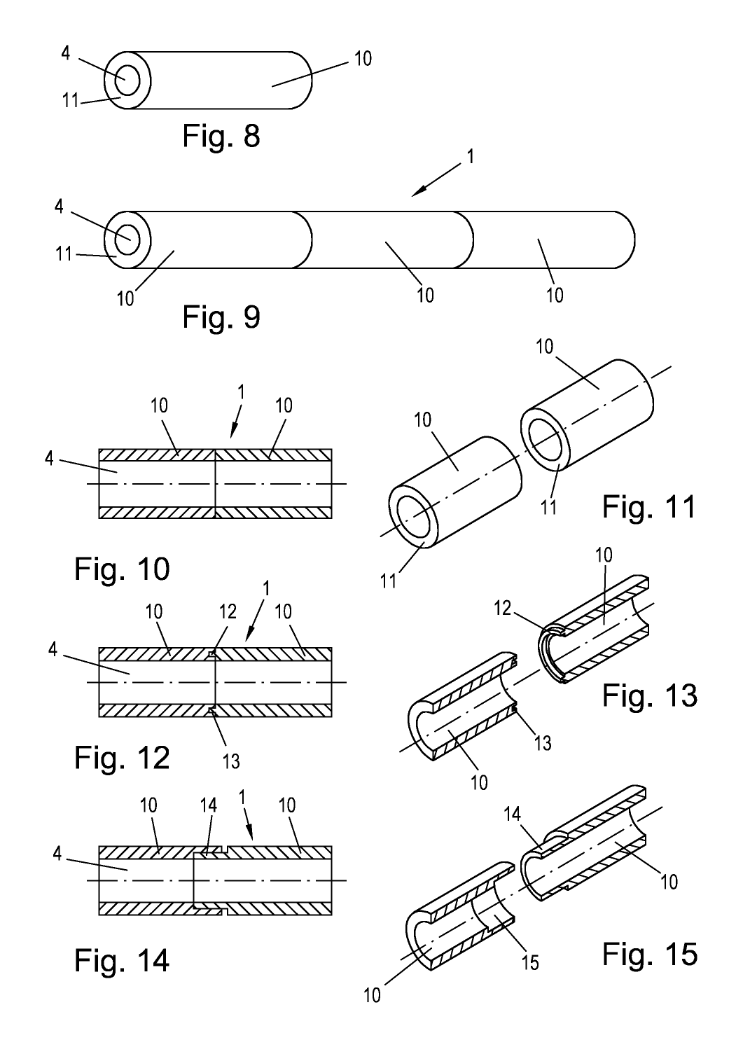

US 2008/0286981 A1 deals with a method for treating semiconductor wafers in a process chamber, whereby titanium nitride and silicon are deposited on the wafers in situ. To this end, in the embodiments shown in FIGS. 4 and 5 of US 2008/0286981 A1, injectors by which gas is introduced are provided in the process chamber. Materials of which the injectors can consist are not disclosed. FIG. 8 from US 2008/0286981 A1 shows that injectors can have an elongated oval cross-section. In FIG. 7, it is also shown that the injectors can have lateral outlet openings. Such outlet openings are also shown in FIG. 8. US 2008/0286981 A1 does not contain any information on the material from which the injectors can be manufactured.

EP 0 582 444 A1 relates to a device for the CVD method, with which high-purity SiC is produced. The device comprises three injector tubes, whose design is shown in FIG. 3. FIG. 3 of EP 0 582 444 A1 shows that three concentric tubes, which define circular channels, are contained in the injector tubes. Only the middle channel is used for feeding gas into a chamber. The outer channels are used for the circulation of coolant. Also, EP 0 582 444 A1 does not contain any information on the material from which the injectors can be produced.

In the known injectors made of quartz glass, there is a problem in that deposits, which develop on the injector made of quartz glass because of the treatment process, detach because of thermal pressure and can impair the proper production of wafers.

Particles (flakings) develop from chipping, which particles are undesirable in the processes of the semiconductor industry.

The object of the invention is to make available an injector that does not cause the above-described problems.

This object is achieved according to the invention with an injector, which has the features of claim 1.

Preferred and advantageous configurations of the injector according to the invention are the subject matter of the subclaims.

Since the injector according to the invention is designed as a tube made of silicon, no thermal stresses that could cause the flaking off of deposits (flakings) are produced. Moreover, the forming of deposits is prevented or at least reduced with the injector according to the invention.

The design, according to the invention, of the tube that forms the injector makes it possible for the injector to consist of multiple pieces of tube, whereby smooth or profiled front surfaces of the pieces of tube are present preferably on the points of joint, which pieces of tube are connected to one another by a crystallization method and/or mechanically to form a tube that forms an injector.

The injector that consists of silicon according to the invention is not necessarily a straight tube. Rather, the injector according to the invention can also be a bent or angled tube.

In order to impart to the injector that is made of silicon according to the invention adequate mechanical stability for its use in an oven for treating wafers with treatment gas, even at elevated temperatures, the profile of the injector is other than round in an exemplary embodiment.

For example, the profile of the injector, in particular in cross-section, can be made rectangular, elongated oval, triangular or star-shaped.

The preferred design of the injector according to the invention with its non-round, i.e., non-circular, profile makes it possible to provide in the injector more than one hollow space (channel) for the feeding of gas for the treatment of the wafer. Two channels have the advantage that various gases can be fed alternately. If one of the channels is blocked, the other channel can be used to feed gas into the furnace for treating wafers, which are inserted into boats.

Here, the term “profile” defines the outer shape of the tube that is used as an injector according to the invention.

The term “non-round” used here comprises all profiles that are not circular in cross-section.

Additional details and features of the invention follow from the description below of preferred embodiments based on the drawings. Here:

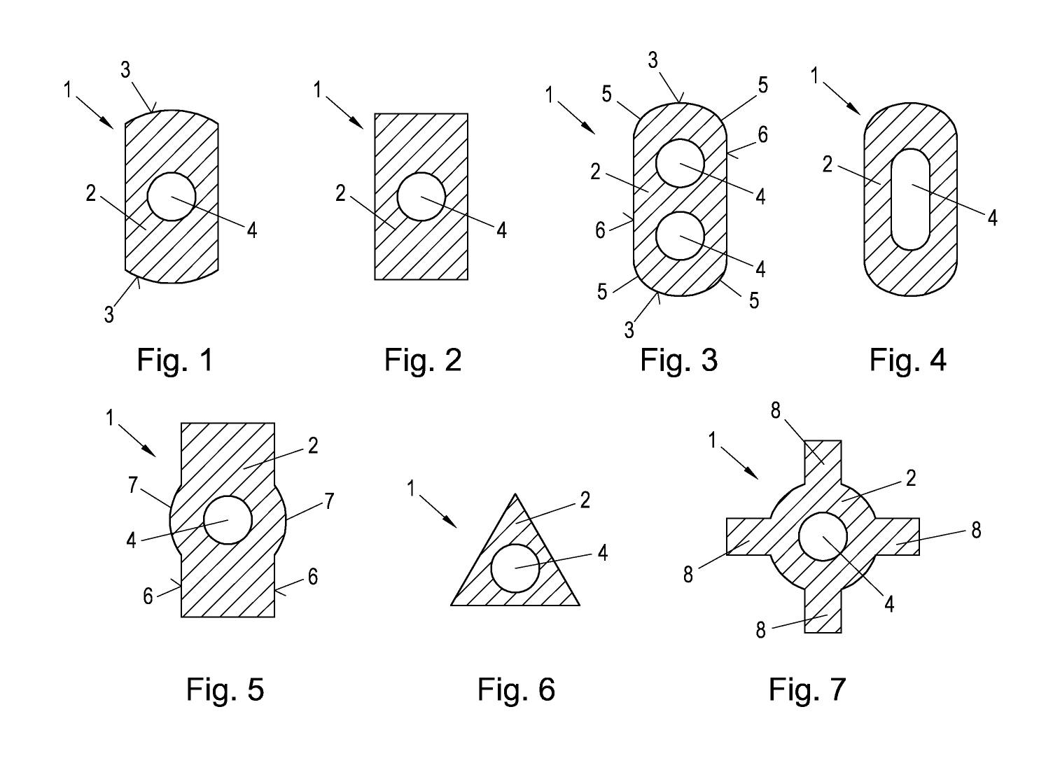

FIGS. 1 to 7 show, in cross-section, various profiles of tubes made of silicon that are used as injectors,

FIG. 8 shows an individual piece of tube,

FIG. 9 shows an injector that consists of three pieces of tube, and

FIGS. 10 to 23 show, partially in section, variants for connecting pieces of tube to one another.

An injector 1 according to the invention, which is manufactured from silicon, is designed as tube 2, which can be straight, bent or angled (e.g., angled by 85-95°).

In the embodiment of an injector 1 made of silicon that is shown in FIG. 1, the tube 2 has an essentially rectangular profile with convex, curved narrow surfaces 3. In the tube 2, a channel 4 with a circular cross-section is provided.

In the embodiment shown in FIG. 2, the profile of the tube 2, which forms the injector 1, is rectangular.

In FIG. 3, an embodiment of a tube 2 that is used as injector 1 is shown, in which tube two channels 4 are provided. The profile of the tube 2 is elongated, whereby the narrow surfaces 3 of the tube, which are convex, turn into the side surfaces 6 of the tube 2 via roundings 5.

FIG. 4 shows a tube 2, which can be used as injector 1, whose profile is similar to the profile shown in FIG. 3, whereby in the tube 2, a channel 4 that is designed elongated in cross-section is provided.

FIG. 5 shows a modification of the embodiment of a tube 2 that is shown in FIG. 2, which tube can be used as injector 1, in which bulges 7 are provided in the area of the channel 4 in the side surfaces 6 of the tube. The profile of the tube 2 that is shown in FIG. 5 can also be defined as the one circular tube with two fins that project outward.

FIG. 6 shows an embodiment of a tube 2, which can be used as injector 1, in which the profile of the tube 2 is an equilateral triangle. As an alternative to an equilateral triangle, the profile of the tube 2 can be an isosceles triangle or any triangle.

FIG. 7 shows an embodiment of a tube 2, which can be used as injector 1, whereby the tube 2 comprises a base element with a circular cross-section, whose outside surface is designed in a concentric manner to the channel 4 in the tube 2. In the embodiment that is shown, stiffening fins 8 project outward from the circular base element, so that a star-shaped profile of the tube 2 is present. The number of stiffening fins 8 should not be four, but rather can also be two (cf. FIG. 5) or three or more than four.

Within the scope of the invention, consideration is given to forming the tube 2 that forms injector 1 from at least two pieces of tube 10.

The end surfaces (front surfaces) of the pieces of tube 10 can be made smooth or profiled. The connection of pieces of tube 10 to one another can be carried out mechanically and/or, if necessary, for example, by a crystallization method.

Some advantageous embodiments for the purpose of increasing mechanical connecting stability are stages or digital designs in the profile of the wall or in the profile of the entire piece of tube 10. Also, a threaded connection of pieces of tube 10 is possible.

FIG. 8 shows a piece of tube 10, from which a tube 2 for an injector 1 according to the invention can be produced by connecting to additional pieces of tube 10 (cf. FIG. 9).

The pieces of tube 10 of FIGS. 8 to 23 can have a shape of the profile, shown in FIGS. 1 to 7, with one or two channels 4.

In a longitudinal section, FIG. 10 shows a tube 2 for an injector 1 that consists of two pieces of tube 10, in which injector the pieces of tube 10 abut one another.

FIG. 11 shows the tube 2 of FIG. 10 in an exploded depiction.

In the case of the tube 2 that consists of two pieces of tube 10, shown in FIGS. 12 and 13, one end of a piece of tube 10 has an annular fin 12 that projects over the end surface 11, which fin engages in an annular groove 13 in the end surface 11 of the other piece of tube 10.

The pieces of tube 10 of the embodiment shown in FIGS. 14 and 15 have mirror-inverted, stepped end surfaces 11, whereby a projecting annular part 14 engages in a recess 15 of the other piece of tube 10 (FIG. 14).

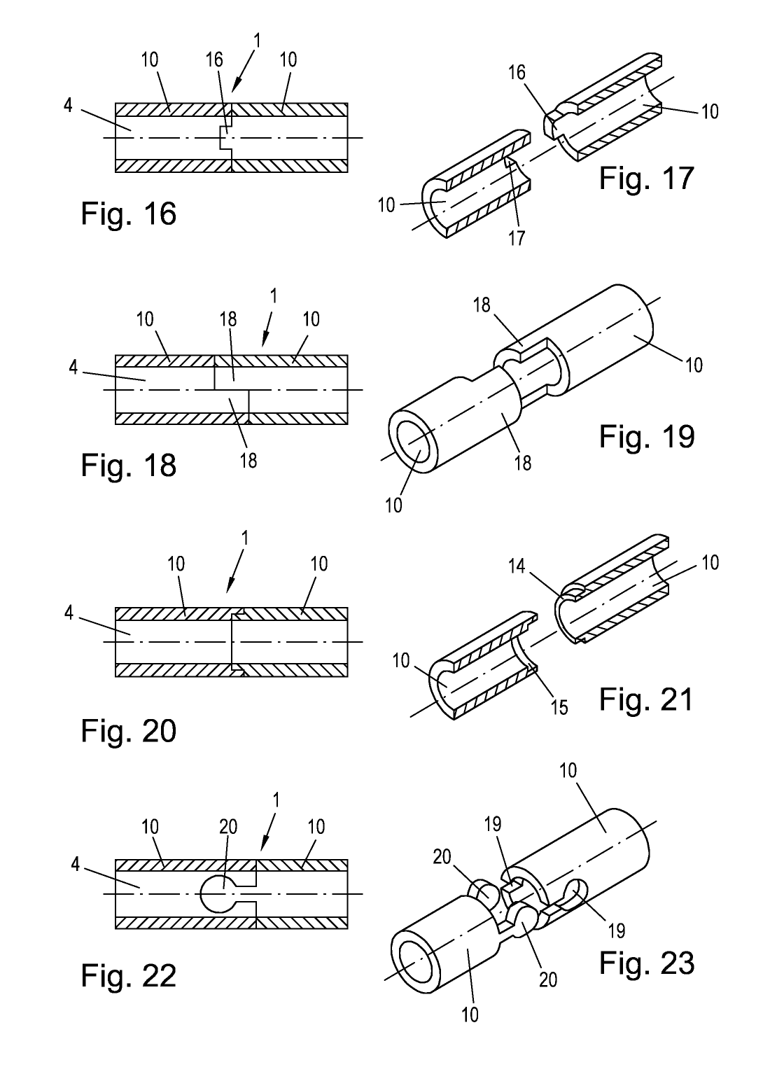

In the embodiment shown in FIGS. 16 and 17, a piece of tube 10 has (at least) one projection 16 on its end surface 11, which projection engages in the wall of the piece of tube 10 in a recess 17 that is open to the end surface 11 of the other piece of tube 10.

The pieces of tube 10 of the embodiment shown in FIGS. 18 and 19 have partial or semi-circular curved attachments 18 on their end surfaces 11, which attachments, in the case of the pieces of tube 10 that are connected to one another, supplement one another to form a closed ring (FIG. 18).

The embodiment shown in FIGS. 20 and 21 corresponds to that of FIGS. 14 and 15, provided that the annular part 14 is designed to be shorter and the recess 15 is designed to be less long.

In the embodiment shown in FIGS. 22 and 23, the pieces of tube 10 are coupled in a positive manner by virtue of the fact that a key-lock-shaped recess 19 open toward the end surface 1 is provided in the wall of a piece of tube 10 and two mirror-inverted formed projections 20 that project from the end surfaces 11 thereof are provided on the other piece of tube 10.

Although the pieces of tube 10 shown in FIGS. 10 to 23 have configurations allowing the connecting of pieces of tubes 10 only on one end in each case, consideration is also given to pieces of tube 10 that are designed on both ends according to one of the embodiments shown in FIGS. 10 to 23, so that tubes 2 that form three or more pieces of tube 10 in order to form injectors 1 can be put together and connected to one another.

Even in the case of pieces of tube 10 that engage in one another in a positive manner (FIGS. 12 to 23), it is taken into consideration according to the invention that the pieces of tube 10 that are put together to form the tube 2 of the injector 1 are connected to one another by a crystallization method.

When using an injector 1 made of silicon according to the invention in processes in which gas is introduced for treatment into a process chamber, in particular in semiconductor technology in the course of the production of chip-containing wafers, the problem of particles developing (flaking) no longer arises—other than in the case of known injectors made of quartz glass.

In particular, it has already turned out to be advantageous that when using injectors 1 according to the invention, fewer contaminants and less particle formation occur.

Another advantage of the injector 1 according to the invention is its extended time of use and in addition the fact that the treatment process is cleaner.

The stability of the injector 1 is increased by the preferred outer shape of the profile of the tube 2 that is used as injector 1 and that is not circular.

As already mentioned and shown in, for example, FIG. 3, when necessary, multiple, for example two, three or more, channels 4 can be provided for the feeding of gas into the tube 2 that is used as injector 1.

Although not shown in the drawings, the outlet openings for the gas (process gas) that are also common in the case of injectors made of quartz glass are provided in the tubes 2 that are used as injectors 1 according to the invention.

In summary, an embodiment of the invention can be described as follows:

An injector 1, which is manufactured from silicon and which makes it possible to introduce gas into process chambers in processes, in particular processes in semiconductor technology, is proposed. The injector 1 is designed as tube 2, which optionally consists of at least two pieces of tube 10, in which outlet openings are provided for the gas to be brought into the process chamber. At least one channel 4 is provided in the tube 2, which is used as injector 1. The profile of the tube 2 that is used as injector 1 is non-round, thus deviates from a circular profile, whereby consideration is given to elongated, triangular or star-shaped profile shapes.

1. An injector (1) for feeding gas into a process chamber, comprising:
a tube (2), in which outlet openings for the gas are provided,
wherein the tube (2) consists of silicon, and
wherein the tube (2) is made in one part or is put together from at least two one-part pieces of tube (10) in each case to form the tube (2).

2. The injector according to claim 1, wherein the profile of the tube (2) that is used as the injector (1) is non-round, by deviating from a circular profile.

3. The injector according to claim 1, wherein at least one channel (4) for the gas is provided in the tube (2).

4. The injector according to claim 1, wherein two channels (4) for the gas, which are arranged to run parallel to one another, are provided in the tube (2).

5. The injector according to claim 1, wherein the profile of the tube (2) that is used as the injector (1) is rectangular.

6. The injector according to claim 5, wherein narrow sides (3) of the tube (2) are convex.

7. The injector according to claim 5, wherein narrow sides (3) of the tube (2) turn into side surfaces (6) of the tube (2) via curvatures (5).

8. The injector according to claim 3, wherein,
the tube (2) that is used as the injector (1) has a base element that has a profile that is curved in a concentric manner to the channel (4) in the tube (2) and
at least two fins (8) project from the base element outward.

9. The injector according to claim 8, wherein the fins (8) are provided diametrically opposite to one another.

10. The injector according to claim 8, wherein exactly two fins (8) are provided.

11. The injector according to claim 8, wherein three, four or more fins (8) are provided.

12. The injector according to claim 1, wherein the tube (2) that is used as the injector (1) has a triangular profile.

13. The injector according to claim 1, wherein the at least one channel (4) for the gas has an elongated cross-sectional shape.

14. The injector according to claim 1, wherein the tube (2) that is used as the injector (1) is put together from at least two pieces of tube (10).

15. The injector according to claim 14, wherein pieces of tube (10) are connected to one another to form the tube (2).

16. The injector according to claim 14, wherein the pieces of tube (10) are made mirror-inverted for a positive connection in the area of one of their end surfaces (11).

17. The injector according to claim 1, wherein,
the profile of the tube (2) is a non-circular profile, and
at least one channel (4) for the gas is provided in the tube (2).

18. The injector according to claim 1, wherein,
the profile of the tube (2) includes at least one straight side, and
at least one channel (4) for the gas is provided in the tube (2).

19. The injector according to claim 6, wherein the narrow sides (3) of the tube (2) turn into the side surfaces (6) of the tube (2) via curvatures (5).

20. The injector according to claim 4, wherein,
the tube (2) has a base element that has a profile that is curved in a concentric manner to the channel (4) in the tube (2) and
at least two fins (8) project from the base element outward.
